(19) United States
(12) Patent Application Publication
(10) Pub. No.: US 2026/0150707 A1
(43) Pub. Date: May 28, 2026

(54) POWER MODULE WITH RELIABILITY FEATURES

(71) Applicant: SEMICONDUCTOR COMPONENTS INDUSTRIES, LLC, Scottsdale, AZ (US)

(72) Inventors: Liangbiao CHEN, Gilbert, AZ (US); Yong LIU, Cumberland Foreside, ME (US)

(73) Assignee: SEMICONDUCTOR COMPONENTS INDUSTRIES, LLC, Scottsdale, AZ (US)

(21) Appl. No.: 18/957,113

(22) Filed: Nov. 22, 2024

(51) Int. Cl. H01L 23/495

(52) U.S. Cl. CPC H10W 70/411

(57) ABSTRACT

A device may include a substrate. A device may include a metal portion of the package coupled to the substrate, the metal portion configured to function as an electrical connection from the semiconductor die. A device may include a dies area on the substrate. A device may include a barrier surrounding at least a portion of the die area. A device may include a flexible material disposed between the die area and the barrier. A device may include an encapsulant surrounding the substrate and the metal portion of the package.

### TECHNICAL FIELD

This description relates to assembling and packaging semiconductor device modules, semiconductor device assemblies, and semiconductor devices. More specifically, this description relates to reliability improvements for a power module.

### SUMMARY

In some aspects, the techniques described herein relate to a package for a semiconductor die, the package including: a substrate; a metal portion of the package coupled to the substrate, the metal portion configured to function as an electrical connection from the semiconductor die; a die area on the substrate; a barrier surrounding at least a portion of the die area; a flexible material disposed between the die area and the barrier; and an encapsulant surrounding the substrate and the metal portion of the package.

In some aspects, the techniques described herein relate to a structure, including: a silicon carbide substrate; a metal layer disposed on the silicon carbide substrate; an array of anchors formed in the metal layer; a passivation layer disposed on the metal layer; and a coating on the passivation layer.

In some aspects, the techniques described herein relate to a method, including: forming an array of anchors in a metal layer on a silicon carbide substrate; forming a channel in an underside of a die attach pad; attaching the silicon carbide substrate to an upper surface of the die attach pad; attaching a copper barrier to the die attach pad, the copper barrier surrounding the silicon carbide substrate; disposing a flexible material at an edge of the silicon carbide substrate; and forming a molding compound around the die attach pad.

### BRIEF DESCRIPTION OF THE DRAWINGS

FIG. 1 is a side elevation view of a power module, according to some implementations of the present disclosure.

FIG. 2 is a top plan view of a power module (e.g., SiC-based power module), according to some implementations of the present disclosure.

FIG. 3 is a cross-sectional view of a chip assembly in a power module (e.g., SiC-based power module), according to some implementations of the present disclosure.

FIG. 4 is a bottom perspective view of a power module (e.g., SiC-based power module), according to some implementations of the present disclosure.

FIG. 5 is a flow diagram illustrating a method of manufacturing a power module (e.g., SiC-based power module), according to some implementations of the present disclosure.

FIGS. 6-8 are plots of simulated reliability results comparing performance of different power modules (e.g., SiC-based power modules), according to some implementations of the present disclosure.

Aspects of the present disclosure are best understood from the following detailed description when read with the accompanying figures. It is noted that, in accordance with common practice in the industry, various features are not necessarily drawn to scale. Dimensions of the various features may be arbitrarily increased or reduced for clarity of discussion. In the drawings, like reference symbols may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings but are provided for context between related views. Also, not all like elements in the drawings are specifically referenced with a reference symbol when multiple instances of an element are illustrated.

### DETAILED DESCRIPTION

The power modules (e.g., high power semiconductor device modules) described herein are is configured for high reliability by implementing various stress reduction features. Examples of stress reduction features that can be incorporated into the power module in any combination can include, for example, a coating (e.g., a silicone coating), a channel (e.g., a grooved channel, recessed channel), an anchor assembly, and/or a barrier (e.g., a copper barrier).

The power modules described herein can be implemented using multiple semiconductor die, substrates (e.g., die attach pads (DAPs)), electrical interconnections, and a molding compound. The power transistors described herein can include, for example, insulated-gate bipolar transistors (IGBTs), power metal-oxide-semiconductor field effect transistors (MOSFETs), and so forth. Fast recovery diodes (FRDs) may be used in conjunction with power transistors. Some high power implementations can be in the form of integrated circuits, while others can include discrete devices built on semiconductor substrates. Electrical interconnections within a high-power semiconductor device module can include, for example, bond wires, conductive spacers, and/or conductive clips. A lead frame (e.g., a conductive or metal portion of a package) can be used to provide external electrical connections (e.g., from external circuitry) to the high-power semiconductor device module. A polymer molding compound can serve as an encapsulant to protect components of the device assembly.

The lead frame can be any type of metal portion (e.g., copper, aluminum) of a package (e.g., leads, terminals) that can be used to connect devices (e.g., semiconductor die) with other components (e.g., components, power and/or so forth external to the package). Although a lead frame is used in many examples and by way of example, any type of metal portion can be used and/or included in the packages described herein.

Some of the high-power chip assemblies described herein can operate at voltages in a range of, for example, about 200 V to about 1000 V. Such high-power chip assemblies, encapsulated as semiconductor device modules, can be used as power converters in various applications, including electric vehicles (EVs), e.g., electric cars, airplanes, or drones, hybrid electric vehicles (HEVs), and industrial applications.

Silicon carbide (SiC) can be used as an alternative substrate material to silicon in the fabrication of integrated circuits, and in particular, in the fabrication of power modules. Some useful properties of SiC-based microchips, e.g., metal-oxide-semiconductor field effect transistors (SiC MOSFETs) include reduced weight, low power consumption, and the ability to sustain high temperature operation. Whereas silicon devices operate at temperatures up to about 120 degrees C, SiC devices can operate at temperatures as high as 500 degrees C to 800 degrees C, due to the high thermal conductivity of SiC, which is about 3.5 times greater than that of silicon. SiC devices are therefore particularly suited for power applications such as electric vehicles (EVs), hybrid electric vehicles (HEVs), solar panels, and industrial applications. SiC devices have been inserted into EV production in vehicle components such as DC-DC converters and on-board fast battery chargers.

In some implementations, discrete packages can experience material failures under thermal cycling conditions. In particular, SiC discrete packages can fail due to the high Young's modulus, e.g., stiffness, of the SiC substrate material. Such failures can include delamination of the top metal layer of the SiC die, and metal sliding/passivation cracks. The passivation layer that is deposited over the top metal layer has been observed to become brittle during temperature cycling reliability testing. As temperatures approach 175 degrees C, the passivation layer can shrink preferentially, causing the underlying metal layer to fail. Passivation cracking can then ensue. Such a progression is referred to as ratcheting-assisted passivation cracking. Other material failures that may occur in SiC packages include passivation cracks due to metal shearing, and back metal peeling on the bottom of the die. Although much of the discussion here in is directed to SiC devices, the concepts described herein can be applied to devices formed from a variety of substrate types including Si, gallium nitride (GaN), and so forth.

Solutions to the passivation cracking and metal peeling failure modes focus on reduction of material stress in the passivation layer. One way to reduce passivation stress is to form a wall around the die to reduce the action of a molding compound (e.g., polymer molding compound, epoxy molding compound (EMC)) on the die top. Another method to reduce passivation stress is to protect the edges of the die, where most of the cracking occurs, by adding a buffer in the form of a soft material, e.g., a silicone coating, around the perimeter of the die. Yet another method to reduce stress is to increase flexibility of the die attach pad. This can be achieved by creating a channel in the die attach pad around the perimeter of the die. Yet another method to reduce stress by controlling metal ratcheting is to add anchors (e.g., copper anchors) around corners and edges of the first aluminum metal layer within the die, which is adjacent to the SiC substrate. Any combination of these measures can be implemented as a reliability enhancement feature for SiC-based power modules.

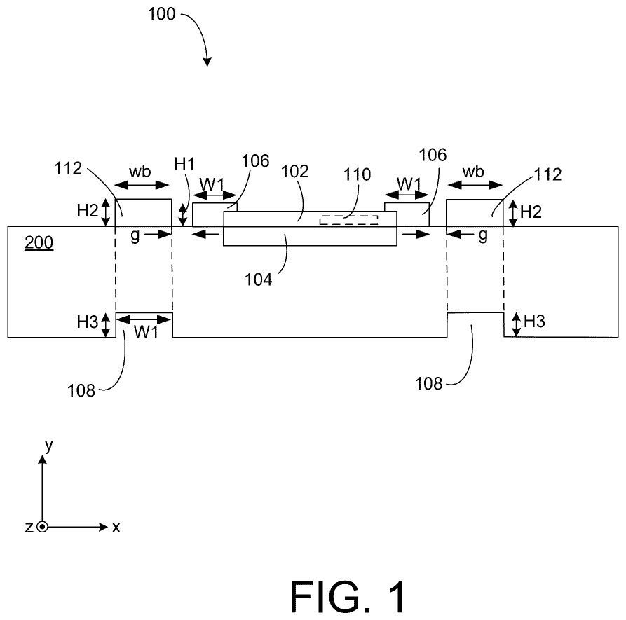

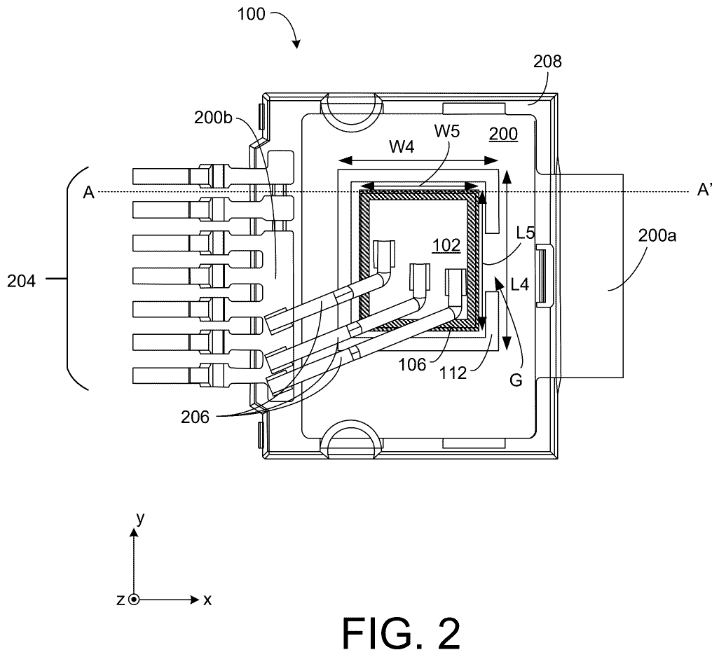

FIG. 1 is a side elevation view of a power module 100 in accordance with some implementations of the present disclosure. The power module 100 includes a chip assembly, or die 102, coupled to (e.g., mounted on) a die attach pad 104 on a lead frame 200. The lead frame 200 can be made of a conductive material (e.g., a highly conductive metal such as copper, aluminum, aluminum copper alloy (AlCu), and so forth). The lead frame 200 is described further with reference to FIG. 2. The die 102 can be attached to, e.g., mounted on, or coupled to, the die attach pad 104 using solder or a sintering layer e.g., a conductive epoxy, a silver (Ag) or copper (Cu) sintering material, and/or a conductive adhesive.

The power module 100 is configured for high reliability by implementing various stress reduction features. Examples of stress reduction features that can be incorporated into the power module 100 are shown in FIG. 1, including a coating 106 (e.g., silicone coating), a channel 108 (e.g., grooved channel), an anchor assembly 110, and a barrier 112 (e.g., a copper barrier). These stress reduction features can be incorporated in any combination that can exclude one or more of the stress reduction features. The side elevation view shown in FIG. 1 shows all four of the stress reduction features at once, thus providing context and showing positions of the features relative to one another.

In some implementations, a die 102 (e.g., semiconductor die) can be fabricated using different substrates, e.g., a hybrid silicon/SiC die configurations in a hybrid die configuration. For example, an IGBT can be fabricated using a SiC substrate, while a controller can be fabricated using a silicon substrate. In some implementations as described herein, more than one die 102 can be fabricated on the same substrate, e.g., on a SiC substrate, suitable for high power applications. In some implementations, the die 102 can include for example, a controller and/or an insulated gate bipolar transistor (IGBT). In some implementations that include multiple die such as die 102, such chip assemblies can include an IGBT and a controller configured to control the IGBT. The controller can also serve as a protection device for the IGBT. For example, the controller can provide temperature protection and/or over-voltage protection for the IGBT. The controller can also limit the amount of current delivered to the IGBT. In some implementations, the controller can be configured to monitor the IGBT. some implementations, other types of semiconductor dies, e.g., silicon carbide MOSFETs, diodes, and so forth, can be used as one or more of the dies 102. In some implementations, a SiC MOSFET can be substituted for the IGBT. In some implementations, fast recovery diodes (FRDs) may be used in conjunction with power transistors.

As noted above, some implementations can include multiple die such as die 102 (e.g., a first die and a second die) and can be coupled to the die attach pad 104 by two different bonding agents. For example, in some implementations, a first die can be mounted to the die attach pad 104 by sintering, while a second die can be mounted to the die attach pad 104 (or s separate die attach pad) using conductive polyimide tape.

A molding compound can be formed over the die 102. The molding compound is not shown in FIG. 1, but is shown in subsequent figures and described below. In some implementations, the molding compound (e.g., molding material or compound, an encapsulation material) can be or can include a non-conducting layer/material. In some implementations, the molding compound is a non-conducting material, such as an epoxy, which can be formed (applied, etc.) using a transfer molding process or a compression molding process. In some implementations, the molding compound can include a separate plastic housing that is included in the semiconductor device assembly.

As mentioned above, the power module 100 is configured for high reliability by implementing various stress reduction features. Four examples of stress reduction features that can be incorporated into the power module 100 are shown in FIG. 1, including the coating 106, the channel 108, the anchor assembly 110, and the barrier 112 (e.g., a copper barrier). The side elevation view shown in FIG. 1 shows all four of the stress reduction features at once, thus providing context and showing positions of the features relative to one another. As noted above, one or more of the stress reduction features can be excluded.

Although the stress reduction features are shown together in the figures, actual implementations of the power module 100 can include various sub-combinations of the four stress reduction features presented herein. For example, each of the four stress reduction features can be implemented alone. In some instances, the four stress reduction features can be implemented in pairs, such as the channel 108 together with the barrier 112 or the anchor assembly 110; the coating 106 together with the channel 108, the anchor assembly 110, or the barrier 112; or the anchor assembly 110 together with the barrier 112. In some instances, the coating 106 can be implemented together with the channel 108 and the barrier 112; In some instances, the coating 106 can be implemented with the channel 108 and the anchor assembly 110. In some instances, the channel 108 can be implemented with the anchor assembly 110 and the barrier 112.

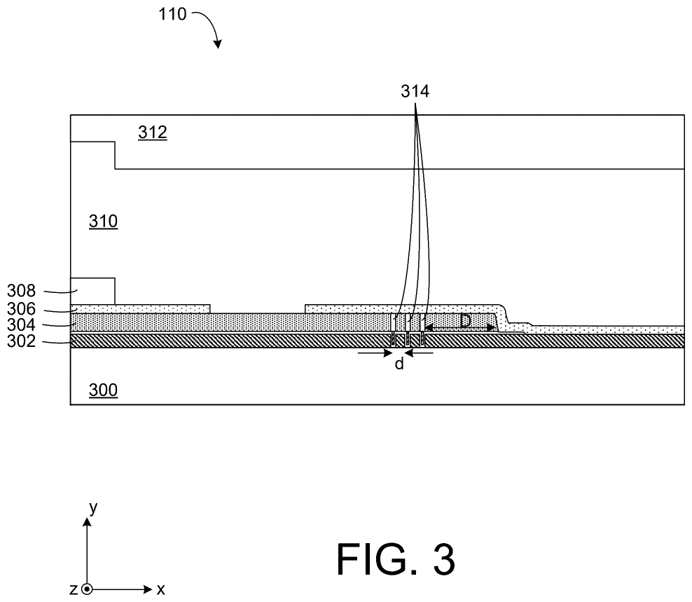

The anchor assembly 110 is part of the internal construction of the die 102, as indicated in FIG. 1 and as described in greater detail below with reference to FIG. 3.

In some implementations, the coating 106 can be disposed around (e.g., positioned around) at least a portion of the perimeter of the die 102. The coating 106 covers a region of the die 102 near a top edge of the die 102. In some implementations, the coating 106 can be in contact with the die 102 to provide a soft material buffer against cracking near the edges of the die 102. The coating 106 can fully or partially cover one or more sides of the die 102. For example, a portion of the coating 106 can cover a top portion of the die 102, a portion of the coating 106 can cover a sidewall of the die 102, and a portion of the coating 106 can be coupled to a top surface of the lead frame 200.

In some implementations, the coating 106 can be applied to the entire perimeter of the die 102. In other words, from a top cross-sectional view the coating 106 can be around an entire perimeter of the die 102. In some implementations, the coating 106 can be applied to one side or to opposite sides of the die 102, instead of the entire perimeter of the die 102. In some implementations, the coating 106 can be applied to discontinuous portions of the perimeter of the die 102. In some implementations, the coating 106 can be coated in a regular or irregular pattern (e.g., in spots or segments) around the die 102. The coating 106 can extend to a height above the height of the die 102.

In some implementations, the coating 106 can have a thickness between about 50 microns and about 100 microns. In some implementations, the coating 106 can have a width W1 of about 0.3 mm, and can overlap the edges of the die 102 by about 0.1 mm. on each side. Although the cross-sectional shape of the coating 106 is shown in FIG. 1 as L-shaped with square corners, in some implementations, the coating 106 can have rounded corners.

In some implementations, the coating 106 can have a height H1. The height H1 can be less than or greater than the width W1. In some implementations, the height H1 can be equal to (or substantially equal to) the width W1.

In some implementations, the barrier 112 can be a wall (e.g., a structure) formed around a perimeter of the coating 106, while being spaced apart from the coating 106 by a gap g. In other words, the coating 106 can be concentrically formed within the perimeter of the barrier 112 when viewed from above (as shown in at least FIG. 2).

In some implementations, a barrier height H2, or thickness, of the barrier 112 can be in a range of about 0.25 mm to about 0.35 mm and a width wb of the barrier 112 can be in a range of about 0.45 mm to about 0.55 mm. In some implementations, a ratio of the width wb of the barrier 112 to the width w of the coating 106 can be about 3:1, and the barrier 112 can be about twice as thick as the coating 106. In some implementations, the barrier 112 can be about 1.0 mm wide and can have a thickness between about 100 and about 200 microns. The barrier height H2 of the barrier 112 can be at or above the height of the die 102 so that the barrier 112 will function to offset, or separate, the molding compound from the top surface of the chip assembly when the power module 100 is packaged. With the barrier 112 in place, the molding compound will be prevented from exerting force on the die top, thus reducing stress on the die.

In some implementations, the height H2 of the barrier 112 can be less than or greater than the width wb. In some implementations, the height H2 can be equal to (or substantially equal to) the width wb.

In some implementations, the height H2 of the barrier 112 can be less than or greater than the height H1 of the coating 106. In some implementations, the height H2 of the barrier 112 can be equal to (or substantially equal to) the height H1 of the coating 106.

The channel 108 is formed in a lower surface of the lead frame 200. Formation of the channel 108 serves to increase flexibility, e.g., reduce stiffness, of the lead frame 200. In some implementations, the channel 108 can be aligned with (e.g., directly underneath, vertically underneath) the barrier 112. In some implementations, the channel 108 (or a portion thereof) can be offset or not vertically aligned with the barrier 112.

In some implementations, the channel 108 can provide stress reduction when the shape of the channel 108 substantially matches, e.g., follows, the shape of the barrier 112. In some implementations, the barrier height H2 is approximately equal to a depth H3 of the channel 108. In some implementations, the barrier height H2 is less than or greater than the depth H3 of the channel 108. In some implementations, the barrier width wb is approximately equal to a width W2 of the channel 108. In some implementations, the barrier width wb is less than or greater than the width W2 of the channel 108.

By reducing the thermal mass and increasing the surface area of the lead frame 200, formation of the channel 108 can facilitate thermal conduction and therefore more efficient cooling of the underside (e.g., bottom side) of the lead frame 200. In some implementations, the underside of the lead frame 200 can be further configured for attachment to a heat sink (not shown).

In some implementations, the die 102 can be coupled to or associated with one or more direct bonded metal (DBM) substrates. In some implementations, the DBM substrate can include an insulating layer disposed between a first metal layer and a second metal layer. The insulating layer can be, for example, a ceramic layer. In some implementations, the insulating layer can be or can include, for example, a ceramic material such as alumina (Al₂O₃) or aluminum nitride (AlN)).

In some implementations, a DBM substrate can be formed by bonding one or more of the metal layers (e.g., first metal layer, second metal layer) to the insulating layer. In some implementations, one or more of the metal layers can be bonded to the insulating layer using, for example, a high-temperature process.

In some implementations, the first metal layer and/or the second metal layer of the DBM substrate can be or can function as a heat sink. In some implementations, the first metal layer and/or the second metal layer can be coupled to a heat sink. In some implementations, at least a portion of one or more of the first metal layer or the second metal layer can be exposed through a molding material.

In some implementations, the first metal layer and/or the second metal layer of the DBM substrate can be or can include a patterned metal layer including one or more electrically conductive traces. In some implementations, the first metal layer and/or the second metal layer can be or can include a patterned layer configured to form one or more electrical circuits, one or more conductive blind and/or through vias, and/or so forth.

In some implementations, the DBM substrate can be, or can include, a direct bonded copper (DBC) substrate (e.g., a DBM with copper metal layers). In some implementations, such as in DBC substrate implementations, the first metal layer and/or the second metal layer is a copper layer.

In some implementations, the power module 100 (e.g., a package including a semiconductor device) can be included in another module (not shown). The power module 100 can be referred to as a package. For example, one or more modules (e.g., power module 100) can be one or more sub modules included within another module. In other words, a first module can be included as a sub module within a second module.

In some implementations, a spacer material can be used with one or more power modules 100. In some implementations, the spacer material can be an epoxy, a silicone adhesive, a conductive material, a non-conductive material, an organic material, a semiconductor material, a metal alloy, a metal foam, a phase change material, etc.

In some implementations, one or more semiconductor die, such as die 102, can be embedded within a layer (rather than surface mounted as shown in FIG. 1). For example, one or more semiconductor die can be disposed within a recess (also can be, or can be referred to as a cavity) of a layer (e.g., a substrate, a printed circuit board, a conductive layer, an insulating layer) of the power module 100.

Although referred to, by way of example, as a lead frame 200 in at least some portions of this detailed description, the lead frame 200 can include any type of conductive portion of a package (e.g., conductive portion, conductive terminal) that can provide an external connection point from a package. Accordingly, the lead frame 200 can be referred to as a conductive portion of the package.

In some implementations, one or more portions of a lead frame 200 can be coupled to a pad (e.g., a bond pad) on at least a portion of a DBM substrate.

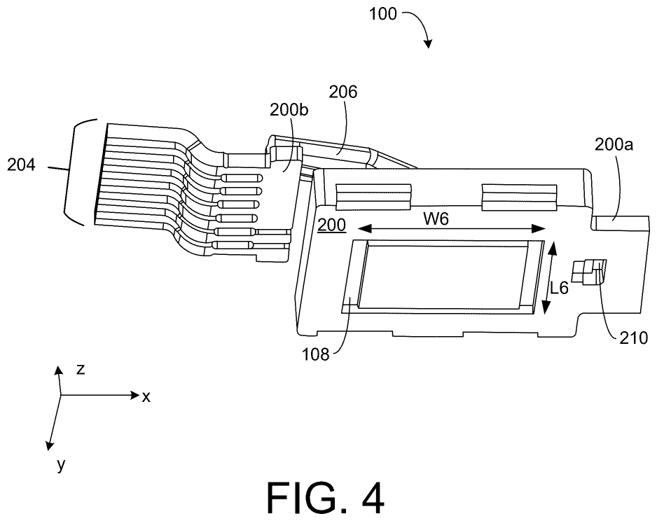

FIG. 2 is a top plan view of the power module 100, in accordance with some implementations of the present disclosure. In addition to the coating 106, the barrier 112, and the lead frame 200 shown in FIG. 1, FIG. 2, shows lead frame extensions (two extensions shown including a first lead frame extension 200a and a second lead frame extension 200b), leads 204 (7 shown), wire bonds 206 (3 shown), and a molding compound 208. In some implementations, a slot 210 (labeled in FIG. 4) can be formed in the first lead frame extension 200a.

The lead frame extension 200a is shown in FIG. 2 as a single lead frame extension 200a. In some implementations, the lead frame extension 200a can instead be replaced with multiple lead frame extensions that may be, for example, smaller in size than the lead frame extension 200a.

In some implementations, the first lead frame extension 200a can be a lateral extension of the lead frame 200, which can be sized to transmit power to the die 102. In some implementations, the leads 204 can extend upward in the z-direction, out of the plane of the die attach pad 104. In some implementations, the second lead frame extension 200b can be adjacent to, but detached from, the die attach pad 104. In some implementations, the wire bonds 206 can couple one or more devices on the die 102 to the second lead frame extension 200b. In some implementations, one or more wire bonds 206 can couple one or more die (such as die 102) to the second lead frame extension 200b.

In some implementations, the second lead frame extension 200b can serve as a landing pad for wire bonds 206, thus coupling the die 102 to the leads 204 for connection to external devices. In some implementations, the leads 204 can be oriented parallel to one another, extending horizontally outward from the second lead frame extension 200b, in the-x direction. In some implementations, one or both of the lead frame extensions 200a and 200b can include copper (or another metal). In some implementations, the wire bonds 206 can include aluminum. In some implementations, the wire bonds can include gold, copper, gold or copper alloys, or other metals. In some implementations, the die attach pad 104 can be a portion of the lead frame 200 that is located directly under the die, e.g., under the die 102, such that the die attach pad 104 is integral to the lead frame 200.

One or more of the wire bonds 206, which can be included in at least some of the implementations described herein, can be replaced with a conductive component. For example, in some implementations, one or more of the wire bonds 206 can be replaced with a conductive clip. The conductive clip can be coupled to another component (e.g., an attach pad, a lead frame, a semiconductor die (e.g., die 102), and/or so forth) using, for example, a solder (e.g., a soldering process), a sintered coupling (e.g., a sintering process), a weld, and/or so forth. In some implementations, one or more of the wire bonds 206 and/or clips can function as an input and/or output power terminal, a signal terminal, a power terminal, and/or so forth.

With reference to FIG. 2, in some implementations, the molding compound 208 can encapsulate (e.g., encompass) the lead frame 200. In some implementations, the second lead frame extension 200b and/or a portion of the first lead frame extension 200a can extend out from the molding compound 208. In some implementations, at least one or more of the leads 204 extend out from the molding compound 208. Within the lead frame 200, the molding compound 208 can encapsulate the die 102 on the die attach pad 104. The molding compound 208 can further encapsulate the coating 106 around the die 102. The molding compound 208 can further encapsulate the barrier 112 surrounding the coating 106. In some implementations, the molding compound can further encapsulate the wire bonds 206.

The plurality of signal terminals (e.g., leads 204, lead frame extension 200a, lead gram extension 200b) can be, or can include, input signal terminals, output signal terminals, and so forth. In some implementations, the plurality of signal terminals can be included in the lead frame 200. In some implementations, the lead frame 200 can include any type of conductive portion of a package (e.g., conductive portion, conductive terminal) that can provide an external connection point from a package. Accordingly, the lead frame 200 can be referred to as a conductive portion of a package or assembly. In some implementations, one or more portions of the lead frame 200 can be coupled to a pad (e.g., a bond pad) on at least a portion of a DBM substrate and/or a semiconductor die (e.g., die 102).

FIG. 2 also shows that the barrier 112 need not be a closed shape. For example, the barrier 112 can be a C-shaped barrier surrounding at least a portion of the die area, as shown, for example, in FIG. 2. For example, in some implementations, the barrier 112 can extend in a continuous path around three of four sides of the die. In some implementations, the barrier 112 can extend in a continuous path around three sides of the die and a portion of the fourth side, with a gap such that the barrier 112 does not form a closed shape. In some implementations, the barrier 112 can be a closed barrier that surrounds the entire die area.

In some implementations, the barrier 112 has a width W4 and a length L4 of the barrier 112 (e.g., in a range of 5.5 mm×6.3 mm to about 6.5 mm×7.7 mm). In some implementations, the width W4 of the barrier 112 can be less than the length L4 of the barrier 112. In some implementations, the width W4 of the barrier 112 can be greater than the length L4 of the barrier 112. In some implementations, the width W4 of the barrier 112 can be equal to (e.g., substantially equal to) the length L4 of the barrier 112.

In some implementations, the coating 106 has a width W5 and a length L5 of the coating 106. In some implementations, the width W5 of the coating 106 can be less than the length L5 of the coating 106. In some implementations, the width W5 of the coating 106 can be greater than the length L5 of the coating 106. In some implementations, the width W5 of the coating 106 can be equal to (e.g., substantially equal to) the length L5 of the coating 106.

As shown in FIG. 2, the coating 106 has a perimeter disposed within a perimeter of the barrier 112. Accordingly, the width W4 is greater than the width W5, and the length L4 is greater than the length L5.

As shown in FIG. 2, the barrier 112 has a gap G (e.g., a break). As shown in FIG. 2, the gap G is opposite the wire bonds 206. As shown in FIG. 2, the gap G is opposite the lead frame extension 200b. In some implementations, the barrier 112 can have more than one gap. Although not shown in FIG. 2, in some implementations, the coating 106 can have one or more gaps (or breaks). In some implementations, the coating 106 can have a gap on a same side of the gap G of the barrier 112.

FIG. 3 is a cross-sectional view of the anchor assembly 110 in a substrate 300, which was introduced in FIG. 1, along the cut line A-A′ shown in FIG. 2, in accordance with some implementations of the present disclosure. In some implementations, the anchor assembly 110 can include copper. FIG. 3 shows layers within the die 102, to which the anchors (e.g., anchors 314 shown in FIG. 3, copper anchors) can be applied. For example, in some implementations, a SiC die substrate can support a dielectric layer 302, a first metal layer 304, a passivation layer 306, a second metal layer 308, a polyimide layer 310, a silicone layer 312, and anchors 314 (e.g., copper anchors) (3 shown).

In some implementations, the anchors 314 can form an array of anchors represented by the three anchors shown in the figures. In some implementations, the number of anchors can be different. In some implementations, more than three anchors can be included. In some implementations, less than three anchors can be included.

In some implementations, the anchors can be spaced apart (e.g., by a distance of about 1.3 μm to about 1.7 μm). The anchors 314 extend through the first metal layer 304. The anchors 314 can have a thickness in a range of about 1.8 μm to about 2.2 μm. In some implementations, the anchors 314 can have widths (e.g., in a range of about 0.4 μm to about 0.6 μm).In some implementations, the anchors can be located a distance D from the edge of the first metal layer 304 (e.g., distance D can be in a range of about 4.5 μm to about 5.5 μm).

In some implementations, the anchors 314 exhibit better mechanical performance than the metal layers, due to superior strength of the anchor structures. In some implementations, the anchors 314 extend through the underlying dielectric layer 302 as well as the first metal layer 304. In some implementations, the dielectric layer 302 can include borophosphosilicate glass (BPSG).

In some implementations, the polyimide layer 310 can have a thickness in a range of about 9 μm to about 11 μm. The polyimide layer 310 passivates the top surface of the die 102, and provides environmental protection for the metal layers. In particular, the polyimide layer 310 can seal the metallization structure against damage from humidity and particulates.

In some implementations, the silicone layer 312 coincides with the coating 106.

FIG. 4 is a bottom perspective view of the power module 100, in accordance with some implementations of the present disclosure. FIG. 4 shows the entire channel 108 formed in a lower surface of the lead frame 200. Formation of the channel 108 can help to reduce stiffness, e.g., increase flexibility, of the die attach pad 104 shown in FIG. 1. In some implementations, the channel 108 can be a closed rectangular channel recessed into the lead frame 200 to a depth in a range of about 0.25 mm to about 0.35 mm. In some implementations, the channel 108 can follow the die dimensions width W6 and length L6, or the dimensions of the barrier 112 surrounding the die 102, so as to relieve any thermal mismatch that may arise between the molding compound and the bottom metal layer of the die 102. In some implementations, the channel 108 has a width in a range of about 0.45 mm to about 0.55 mm. In some implementations, the outer dimensions width W6×length L6 of the channel can be about 6.15 mm×6.95 mm. In some implementations, one or more dimensions of the channel 108 in the lower surface of the lead frame 200 can be matched to corresponding dimensions of the barrier 112 on the opposite, e.g., upper surface of the die attach pad 104.

In some implementations, the width W4 of the barrier 112 is greater than or equal to the width W6 of the channel 108. In some implementations, the length L4 of the barrier 112 is greater than or equal to the length L6 of the channel 108. In some implementations, the width W4 of the barrier 112 is less than the width W6 of the channel 108. In some implementations, the length L4 of the barrier 112 is less than the length L6 of the channel 108.

FIG. 4 further shows how the first lead frame extension 200a can be oriented with respect to the lead frame 200. For example, in some implementations, the first lead frame extension 200a can be co-planar with the lead frame 200.

FIG. 4 further illustrates how the second lead frame extension 200b can be oriented with respect to the lead frame 200. For example, in some implementations, the second lead frame extension 200b can be positioned above, and separate from, the lead frame 200, so that electrical and thermal connections to the lead frame extension 200b are provided by the wire bonds 206. In addition to providing connectivity, the wire bonds 206 can serve to drain heat away from the die 102 for dissipation via the leads 204. Space between the lead frame 200 and the second lead frame extension 200b can facilitate further heat dissipation. In some implementations, the second lead frame extension 200b is spaced apart from the lead frame 200 horizontally by a distance of about 0.2 mm to about 0.4 mm, and vertically by a distance of about 0.6 mm to about 0.8 mm.

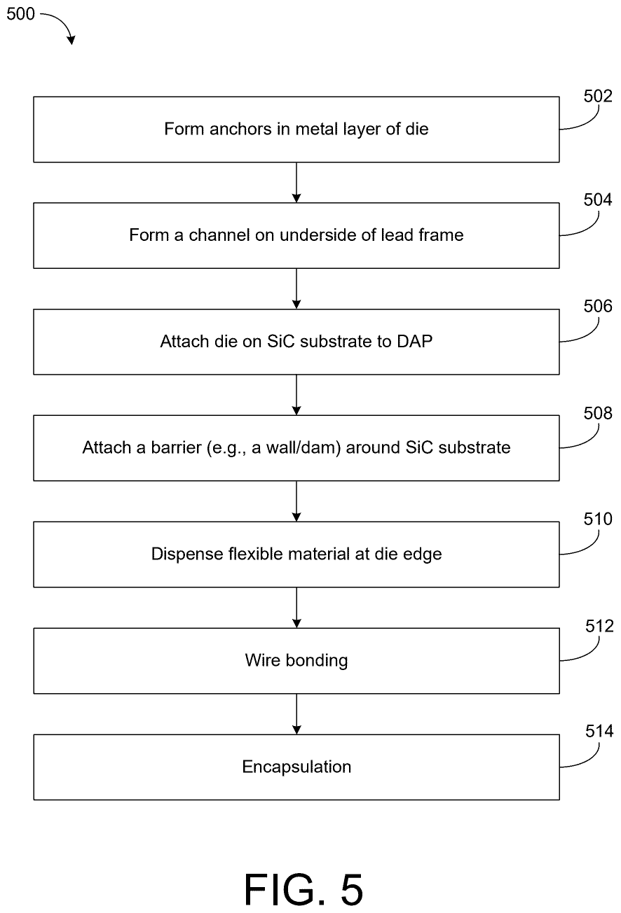

FIG. 5 is a flow chart illustrating a method 500 for fabricating the power module 100, according to some implementations of the present disclosure. Operations of method 500 can be performed in a different order, or not performed, depending on specific applications. It is noted that method 500 may not produce a complete power module 100. Accordingly, it is understood that additional processes can be provided before, during, or after method 500, and that some of these additional processes may be briefly described herein.

Operations 502-510 can be carried out to form the power module 100 according to some implementations as described above, with reference to FIGS. 1-4.

At 502, the method 500 includes forming an array of anchors 314 in the first metal layer 304 of the die 102 on a SiC substrate, as shown in FIG, 3. The first metal layer 304, e.g., an aluminum layer, or an aluminum-copper (Al—Cu) layer, can be formed on, e.g., bonded to, sputtered on, diffused onto, heat-formed on, the non-conductive layer 302. The metal layer 304 can then be patterned at the distance D away from the edge of the metal layer 304, by removing portions of the metal layer using an etching process, to form a series of vertical parallel trenches. The trenches can then be filled with copper, e.g., by an electroplating or electro-less plating process. Following the formation of the anchors 314 (shown in FIG. 3), the first metal layer 304 can be covered with the passivation layer 306. Openings can be formed in the passivation layer 306 to create contacts to the first metal layer 304.

At 504, the method 500 includes forming the channel 108 on an underside of the die attach pad 104 after formation of the passivation layer 306. The channel can be created by patterning the underside of the copper lead frame 200 opposite, e.g., underneath, the die attach pad 104, and using an etching process.

At 506, the method 500 includes attaching the die 102 to the die attach pad 104 using a die attach (DA) material, wherein the DA material can be solder and/or metal sintering including silver (Ag) sintering. For example, the sintering process applies high temperatures and pressures to a powder to remove gaps between the particles, and thus densify the powder. In some embodiments, sintered silver has superior material properties when compared to solder, including a higher thermal and electrical conductivity, and higher reliability. The effectiveness of sintering is proportional to pressure and bonding time. In some implementations, a copper or silver paste can be mixed with the sintering powder and substituted for solder in the solder printing process. Copper sintering is generally inferior to silver sintering due to lower bonding strength, higher process temperatures, and copper oxidation. At 508, the method 500 includes attaching the barrier 112 around the die 102. The barrier 112 can be pre-formed (e.g., fabricated and then attached) and can be installed at the same time as the die attach process. The barrier 112 can be attached using solder (e.g., a lead-free solder) or sintering (e.g., silver sintering).

At 510, the method 500 includes disposing a flexible material around edges of the die, e.g., around the die 102. The flexible material is more pliable than metal, for example, a silicone gel. Disposing the flexible material can include dispensing the silicone gel between the die area and the barrier. The silicone gel can be dispensed to fill a gap around a perimeter of the die 102. Following the dispense operation, a cure step can be performed in which the silicone gel is exposed to ultraviolet light or heat to solidify the gel while maintaining its elasticity.

At 512, the method 500 includes wire bonding to couple circuits in the die 102 to the leads 204. The wire bonds 206 can be attached using solder and/or sintering, e.g., silver sintering. In some implementations, one or more conductive clips (e.g., metal clips) can be used in conjunction with and/or in place of one or more of the wire bonds 206. In some implementations, one or more of the wire bonds can be replaced with one or more conductive clips.

At 514, the method 500 includes encapsulation, e.g., forming an encapsulant such as a molding material, around the die 102, the die attach pad 104, the coating 106, and the barrier 112. For example, the encapsulant can include a polymer molding material, e.g., a compound such as the molding compound 208, that serves to seal and protect the various components of the power module 100. Encapsulation can be accomplished by, for example, a process of injection molding or a process of transfer molding.

In some implementations, soldering can be, or can include, a process of joining two surfaces (e.g., metal surfaces) together using a molten filler metal (e.g., metal alloy, Tin (Sn), Lead (Pb), Silver (Ag), Copper (Cu)) that can be referred to as a solder.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder, a sintering (e.g., silver, copper) material, and/or other metal-to-metal type bonding materials.

In some implementations, a coupling of components can be performed using, for example, a solder process, a sintering process (e.g., a silver sintering process, a copper sintering process), and/or other metal-to-metal type bonding processes.

In example implementations, the power module 100 can be a hybrid device package, e.g., an integrated circuit (IC) package that includes a plurality of semiconductor dies that are integrated onto, e.g., attached to a die attach pad of, a unifying electronic power substrate, The electronic power substrate can be, for example, a ceramic substrate, a direct bond copper (DBC) substrate, an active metal brazed (AMB) substrate, an elastomeric substrate, an organic substrate, a phenolic substrate, or a printed circuit board (PCB) substrate. The different semiconductor dies may be fabricated on different semiconductor wafers or materials. For example, the plurality of semiconductor dies in the IC package may include a first die formed using a silicon material and a second die formed using a silicon carbide material. In example implementations, multiple semiconductor dies may be electrically connected to one another by a connector, e.g. a wire bond, or an electrical clip, extending directly between the dies. In some implementations, a first die can be connected to a second die via a trace formed in a first conductive layer (e.g., a metal layer) of an electronic power substrate. One or more of the semiconductor die may be also connected to lead frame posts by electrical connections such as wire bonds.

In some implementations, one or more semiconductor die (e.g., one or more semiconductor components) can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRDs), a diode, and/or so forth. In some implementations, one or more semiconductor die can be (e.g., can be a portion of), or can include, a component for an electrical vehicle (EV).

More than one semiconductor die can be included in the implementations described herein. In some implementations, different semiconductor die (when more than one semiconductor die is included in some of the implementations) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a first semiconductor die may be connected to a second of the semiconductor die, for example, by an electrical connection (e.g., a wire bond, an electrical clip) extending directly from the first die to the second die, or connected through a trace formed in the first conductive layer (e.g., a metal layer) of an electronic power substrate. The first of the plurality of semiconductor dies may be also connected to lead frame posts by electrical connections such as wire bonds or clips.

In example implementations, a package (e.g., a power module) can be a hybrid device package that includes a semiconductor die or a plurality of semiconductor dies that are integrated onto to a unifying electronic power substrate (e.g., a ceramic substrate, a DBM or DBC substrate, an AMB substrate, an elastomeric substrate, an organic substrate, a phenolic substrate, or a PCB/FR-4 substrate). In some implementations, multiple semiconductor devices (e.g., can be fabricated on the same substrate such as a SiC substrate) suitable for high power applications.

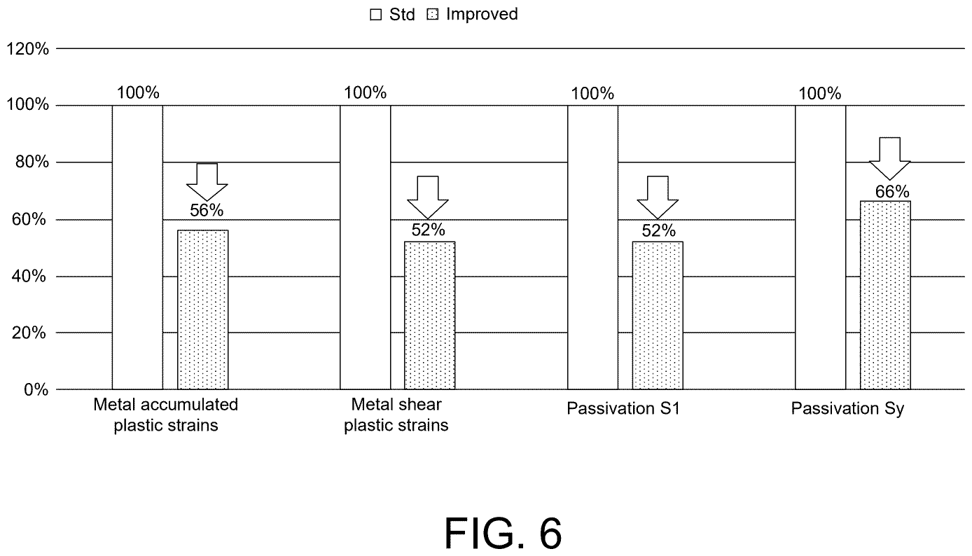

FIGS. 6-8 show plots of simulated reliability tests, according to some implementations of the present disclosure. The reliability tests are simulations of thermal cycling to check performance of the reliability improvement measures described above. Each series of tests illustrated in the plots includes two strain measurements in the top metal layer, e.g., the second metal layer 308, and two measurements of the passivation layer 306. The simulated strain measurements include metal accumulated plastic strain and metal shear plastic strain. The simulated passivation layer measurements include passivation strain in two different directions representing passivation tensile stress and peeling stress in the passivation layer 306. Metal plastic deformation is an indicator of metal sliding / ratcheting, and greatly reduces passivation tensile and peeling stress. Tests are performed after four temperature cycles, in which the temperature is lowered to −55 C. Simulated temperature cycling can entail running a set of between four and eight cycles, representing real-world tests of 1000-2000 temperature cycles. Each set of plots compares performance of the power module 100 with and without the four improvements described above: the anchors 314, the barrier 112, the coating 106, and the channel 108. The data representing the standard power module 100 without improvements is normalized to100%.

FIG. 6 shows bar graphs for a first comparison of simulated temperature cycling performance of the power modules described herein, according to some implementations of the present disclosure. In each set of plots, simulated reliability test results for the standard SiC-based power module are shown on the left and simulated reliability test results for the improved power module 100 are shown in the right. Reductions in accumulated plastic strain and shear plastic strain in the top metal layer were 56% and 52%, respectively, while reductions in passivation layer tensile stress and passivation layer peeling stress were 52% and 66%, respectively.

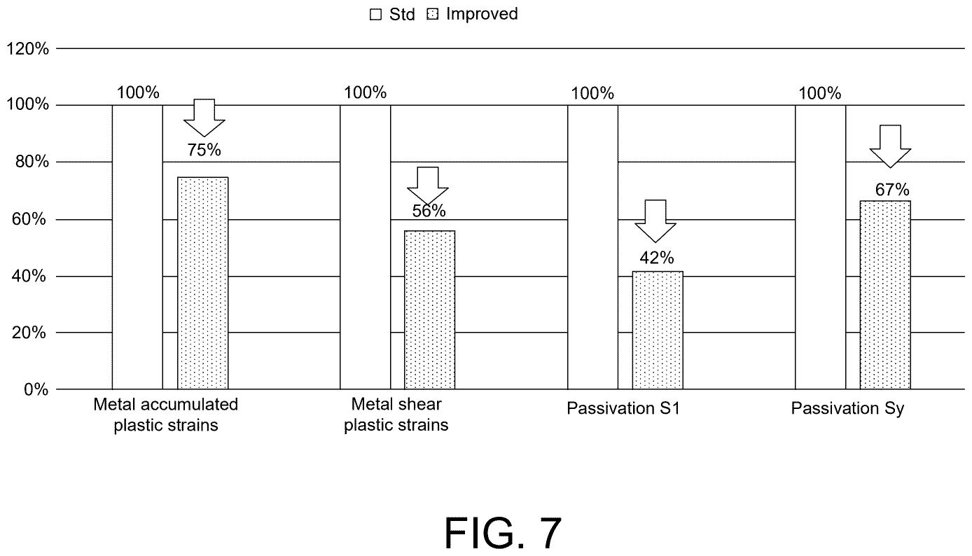

FIG. 7 shows bar graphs for a second comparison of simulated temperature cycling performance of the power modules described herein, according to some implementations of the present disclosure. The second comparison is for an extreme case, in which the entire thickness of the metal layer is assumed to yield, e.g., fail, at a pressure of 50 MPa. This would be an unusual occurrence because a metal layer is more vulnerable at the corners and edges, so the entire layer would not yield at once. That is, metal layers tend to yield from the outside toward the center, so that the center of the metal layer is the last portion to fail. In each set of plots, simulated reliability test results for the standard SiC-based power module are shown on the left and simulated reliability test results for the improved SiC-based power module 100 are shown in the right. Even in the extreme case, the simulations showed much lower plastic strain and passivation stress, and therefore a much lower risk of passivation cracking or peeling. Reductions in accumulated plastic strain and shear plastic strain in the top metal layer were 75% and 56%, respectively, while reductions in passivation layer tensile stress and passivation layer peeling stress were 42% and 67%, respectively.

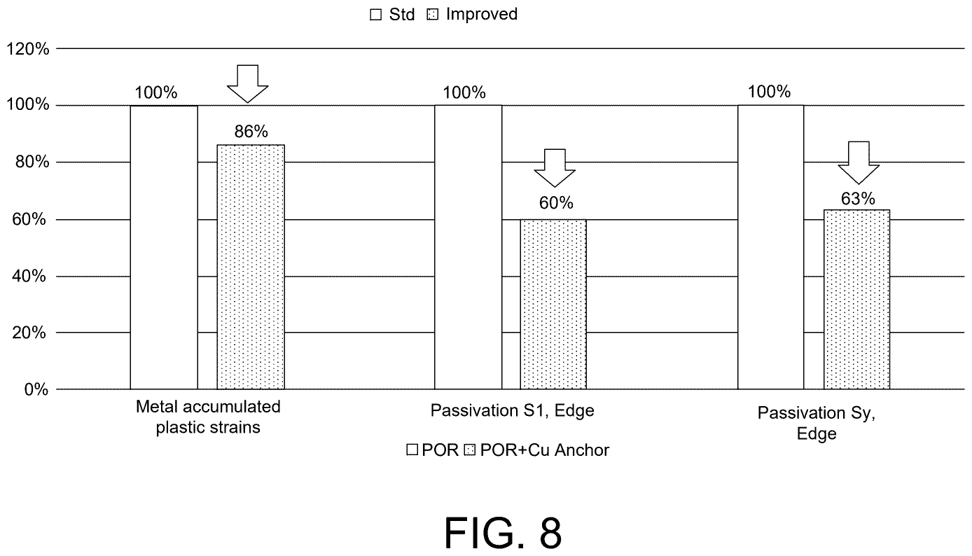

FIG. 8 shows bar graphs for a third comparison of simulated temperature cycling performance of the power modules described herein, according to some implementations of the present disclosure. The third comparison is also for the extreme case, similar to the case shown in FIG. 7 in which all metal layers are assumed to yield, e.g., fail, at a pressure of 50 MPa. However, in FIG. 8, the only improvement included is the anchors 314. In each set of plots, simulated reliability test results for the standard SiC-based power module are shown on the left and simulated reliability test results for the improved SiC-based power module 100 are shown in the right. In the extreme case, the simulations showed significant reductions in metal strain and passivation stress when only the anchors were implemented. The reduction in shear plastic strain in the top metal layer was 86%, while reductions in passivation layer tensile stress and passivation layer peeling stress at the edge of the passivation layer 306 were 60% and 63%, respectively.

As described above, passivation cracking and metal peeling failure modes in silicon carbide-based power modules can be addressed by including structures that relieve passivation layer stress. Such structures can include a copper barrier around the die, a coating in contact with the perimeter of the die, a channel in the lead frame, and forming an array of anchors in the first metal layer. Any combination of these measures can be implemented as a reliability enhancement feature for SiC-based power modules. Simulations of temperature cycling tests show a decrease in failure modes ranging from 14% to 58%, compared with power modules that do not include the stress-relieving structures.

Example 1. A package for a semiconductor die, the package comprising: a substrate; a metal portion of the package coupled to the substrate, the metal portion configured to function as an electrical connection from the semiconductor die; a die area on the substrate; a barrier surrounding at least a portion of the die area; a flexible material disposed between the die area and the barrier; and an encapsulant surrounding the substrate and the metal portion of the package.

Example 2. The package of Example 1, further comprising a channel formed in an underside of the metal portion of the package.

Example 3. The package of Example 1, wherein the semiconductor die includes silicon carbide.

Example 4. The package of Example 1, wherein the semiconductor die includes a metal layer in which an array of anchors is formed.

Example 5. The package of Example 1, wherein the flexible material includes a silicone gel.

Example 6. The package of Example 1, wherein the flexible material is in contact with the semiconductor die.

Example 7. The package of Example 1, wherein the flexible material extends above a top surface of the semiconductor die.

Example 8. The package of Example 1, further comprising a channel formed in an underside of the metal portion of the package, the barrier has a barrier height that is substantially equal to a depth of the channel.

Example 9. The package of Example 1, further comprising a channel formed in an underside of the metal portion of the package, the barrier has a width substantially equal to a width of the channel.

Example 10. The package of Example 1, wherein the barrier is attached to the substrate by at least one of solder, an epoxy material, or silver sintering.

Example 11. The package of Example 1, wherein the barrier extends above a top surface of the flexible material.

Example 12. A structure, comprising: a silicon carbide substrate; a metal layer disposed on the silicon carbide substrate; an array of anchors formed in the metal layer; a passivation layer disposed on the metal layer; and a coating on the passivation layer.

Example 13. The structure of Example 12, wherein the metal layer includes aluminum, and the array of anchors includes copper anchors.

Example 14. The structure of Example 12, wherein the array of anchors extends through an entire thickness of the metal layer.

Example 15. The structure of Example 12, further comprising a second metal layer and a polyimide layer over the second metal layer.

Example 16. The structure of Example 12, wherein the coating is a silicone coating.

Example 17. A method, comprising: forming an array of anchors in a metal layer on a silicon carbide substrate; forming a channel in an underside of a die attach pad; attaching the silicon carbide substrate to an upper surface of the die attach pad; attaching a copper barrier to the die attach pad, the copper barrier surrounding the silicon carbide substrate; disposing a flexible material at an edge of the silicon carbide substrate; and forming a molding compound around the die attach pad.

Example 18. The method of Example 17, wherein disposing the flexible material comprises dispensing a silicone gel around a perimeter of the silicon carbide substrate.

Example 19. The method of Example 18, wherein dispensing the silicone gel includes dispensing an amount of silicone gel to fill a gap around the perimeter.

Example 20. The method of Example 17, wherein attaching the copper barrier comprises aligning the copper barrier to the channel.

Example 21. The method of Example 17, wherein forming the molding compound comprises forming the molding compound around portions of a lead frame integral to the die attach pad.

Example 22. The method of Example 17, wherein forming the array of anchors comprises removing portions of the metal layer using an etching process.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

While certain features of the described implementations have been illustrated as described herein, many modifications, substitutions, changes, and equivalents will now occur to those skilled in the art. For instance, features illustrated with respect to one implementation can, where appropriate, also be included in other implementations. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

1. A package for a semiconductor die, the package comprising:
a substrate;
a metal portion of the package coupled to the substrate, the metal portion configured to function as an electrical connection from the semiconductor die;
a die area on the substrate;
a barrier surrounding at least a portion of the die area;
a flexible material disposed between the die area and the barrier; and
an encapsulant surrounding the substrate and the metal portion of the package.

2. The package of claim 1, further comprising a channel formed in an underside of the metal portion of the package.

3. The package of claim 1, wherein the semiconductor die includes silicon carbide.

4. The package of claim 1, wherein the semiconductor die includes a metal layer in which an array of anchors is formed.

5. The package of claim 1, wherein the flexible material includes a silicone gel.

6. The package of claim 1, wherein the flexible material is in contact with the semiconductor die.

7. The package of claim 1, wherein the flexible material extends above a top surface of the semiconductor die.

8. The package of claim 1, further comprising a channel formed in an underside of the metal portion of the package, the barrier has a barrier height that is substantially equal to a depth of the channel.

9. The package of claim 1, further comprising a channel formed in an underside of the metal portion of the package, the barrier has a width substantially equal to a width of the channel.

10. The package of claim 1, wherein the barrier is attached to the substrate by at least one of solder, an epoxy material, or silver sintering.

11. The package of claim 1, wherein the barrier extends above a top surface of the flexible material.

12. A structure, comprising:
a silicon carbide substrate;
a metal layer disposed on the silicon carbide substrate;
an array of anchors formed in the metal layer;
a passivation layer disposed on the metal layer; and
a coating on the passivation layer.

13. The structure of claim 12, wherein the metal layer includes aluminum, and the array of anchors includes copper anchors.

14. The structure of claim 12, wherein the array of anchors extends through an entire thickness of the metal layer.

15. The structure of claim 12, further comprising a second metal layer and a polyimide layer over the second metal layer.

16. The structure of claim 12, wherein the coating is a silicone coating.

17. A method, comprising:
forming an array of anchors in a metal layer on a silicon carbide substrate;
forming a channel in an underside of a die attach pad;
attaching the silicon carbide substrate to an upper surface of the die attach pad;
attaching a copper barrier to the die attach pad, the copper barrier surrounding the silicon carbide substrate;
disposing a flexible material at an edge of the silicon carbide substrate; and
forming a molding compound around the die attach pad.

18. The method of claim 17, wherein disposing the flexible material comprises dispensing a silicone gel around a perimeter of the silicon carbide substrate.

19. The method of claim 18, wherein dispensing the silicone gel includes dispensing an amount of silicone gel to fill a gap around the perimeter.

20. The method of claim 17, wherein attaching the copper barrier comprises aligning the copper barrier to the channel.

21. The method of claim 17, wherein forming the molding compound comprises forming the molding compound around portions of a lead frame integral to the die attach pad.

22. The method of claim 17, wherein forming the array of anchors comprises removing portions of the metal layer using an etching process.
